(19) United States
(12) Patent Application Publication
(10) Pub. No.: US 2025/0076351 A1
(43) Pub. Date: Mar. 6, 2025

(54) Voltage Sensing Lead Termination

(71) Applicant: Grace Technologies, Inc., Davenport, IA (US)

(72) Inventors: Aaron Robert Pasker, Cedar Rapids, IA (US); Philip Brown Allen, Davenport, IA (US); Roger S. Clarke, Santa Claus, IN (US); Abbey Marie-Wilder Shults, Moline, IL (US)

(73) Assignee: Grace Technologies, Inc., Davenport, IA (US)

(21) Appl. No.: 18/825,913

(22) Filed: Sep. 5, 2024

Related U.S. Application Data
(60) Provisional application No. 63/580,727, filed on Sep. 6, 2023.

(51) Int. Cl. G01R 19/155

(52) U.S. Cl. CPC G01R 19/155

(57) ABSTRACT

A voltage sense lead and continuity termination (VSLT) assembly module for use with a source conductor of a power source includes a first voltage sense lead and continuity termination (VSLT) circuit, and a second voltage sense lead and continuity termination (VSLT) circuit, wherein the first VSLT circuit is electrically connected to the source conductor for a phase of the power source at a first voltage termination lead (VTL) connection point, wherein the second VSLT circuit is electrically connected to the source conductor for the phase of the power source at a second voltage termination lead (VTL) connection point, and wherein the first VTL connection point and the second VTL connection point are positioned at the source conductor such that a conductive bridge of the source conductor extends between the first VTL connection point and the second VTL connection point. The VSLT may be used in an Absence of Voltage Tester (AVT) or a power supply conversion circuit or otherwise.

### RELATED APPLICATION

This application claims priority to U.S. Provisional Patent Application No. 63/580,727, filed Sep. 6, 2023.

### FIELD OF THE DISCLOSURE

The present disclosure relates to voltage sensing lead and continuity termination (VSLT). More particularly, but not exclusively, the present disclosure relates to the use of VSLTs in absence of voltage testing and power supplies.

### BACKGROUND OF THE ART

Although various aspects of the present disclosure have utility in applications outside of absence of voltage testing, for purposes of explanation, the following background focuses on absence of voltage testing and the absence of voltage tester (AVT) and in the context of testing electrical energy for 1, 2 & 3-phase and DC power.

An AVT is a permanently mounted device inside an electrical panel that provides workers with a single outside-the-panel-display when a TEST activation illuminates a GREEN SAFE LED indication once all SOURCE conductors have been verified to ZERO VOLTAGE, which is defined as less than 3 Volts RMS (3V TEST). The goal of an AVT is twofold; verify that ZERO VOLTAGE exists between L1, L2, L3, & GRD and that all the VOLTAGE SENSE LEADs are connected to the SOURCE. Electrical safety distinguished between “voltage presence” and “absence-of-voltage verification”-just because “voltage presence” indicators are off, does not mean that absence-of-voltage has been established. Until the AVT was developed, qualified electrical workers could only use certified voltage test instruments to test for voltage between all SOURCE conductors and GRD, which involved this process:
Test the voltmeter to a known electrical source (120 VAC outlet)
Test each line-to-line and each line-to-GRD: L1-L2, L1-L3, L2-L3, L1-GRD, L2-GRD, L3-GRD.
Re-test the voltmeter to a known source.

Despite the promulgation of various standards and attempts at improving operation of AVTs, numerous problems remain. Some of these problems relate to the amount of energy which may associated with a line voltage which may, for example, be 600 volts. This results in a need for large AVT devices to accommodate this line voltage. For example, where there is high voltage, power supply circuitry may be needed to step-down and condition voltage signals to a point where it can be used to power circuitry in the AVT. This may be further complicated where the AVT uses digital circuitry such as microcontrollers, analog-to-digital converters, and digital logical circuitry which requires a power supply which provides consistent, clean power. In addition, use of such circuitry may further generate significant amounts of heat which must be dissipated resulting in larger heat sinks further expanding the size of AVTs. AVTs may include an independent power source such as a battery. The more power required by the AVT, generally the larger the internal power supply, the battery or other independent power source adding further constraints on the size of the AVT.

Thus, there are numerous problems associated with AVTs.

### SUMMARY

Therefore, it is a primary object, feature, or advantage to improve over the state of the art.

It is a further object, feature, or advantage to provide an improved absence of voltage tester.

It is a still further object, feature, or advantage to provide an absence of voltage tester which meets or exceeds applicable safety standards.

It is a still further object, feature, or advantage to provide an absence of voltage tester which relies upon an analog circuit in order to improve reliability.

It is another object, feature, or advantage to use low power, which results in smaller size.

Another object, feature, or advantage is to provide an absence of voltage tester which is small in size and may be installed in tight spaces.

Yet another object, feature, or advantage is to provide an absence of voltage tester which uses Voltage Sense Lead and Continuity Termination (VSLT) printed circuit boards (PCBs) that provide an AC current limiting functionality with two distinct functions: 1) The ability to supply low voltage current limited AC power for 1, 2 or 3 phases for the circuit logic supply; 2) enables a pathway for a bi-directional (+/−side of the AC sinewave) continuity test circuit that ensure connection to the SOURCE, 3) provides a pathway for a <3V RMS voltage test input. 4) provide inherent surge protection and less heat generation for the AVT with input passive resistors and a twisted pair connection that reduce electrical noise into the main circuit.

A further object, feature, or advantage is to provide an absence of voltage tester which uses Voltage Sense Lead and Continuity Termination (VSLT) printed circuit boards (PCBs) such that almost no panel space is required.

A still further object, feature, or advantage is to provide an absence of voltage tester which enables inherent voltage sensing with two separate connections per phase.

Another object, feature, or advantage is an absence of voltage tester which indicates both in normal operation and during test function whether voltage sensing leads have a connection.

A further object, feature, or advantage allows for continuity testing in at least one direction or alternatively, continuity testing in both directions for a test.

Yet another object, feature, or advantage is an absence of voltage tester which has error-proof source termination.

A further object, feature, or advantage is to reduce installation time and accuracy for installation of an AVT.

A still further object, feature, or advantage is to use VSLT PCBs which are mounted directly on conductions, lugs, fuse block, bus bars and the conductors that function as additional heat sinks for the heat generated by the VSLT components.

Another object, feature, or advantage is an AVT with a connector-less design which may be installed from outside the panel through a hole (e.g. a 30 mm hole) in a panel with a single assembly.

Yet another object, feature, or advantage is to provide an AVT with an improved human machine interface.

A further object, feature, or advantage is to provide an AVT which provides electricians with additional information about an electrical system where voltage is present.

A still further object, feature, or advantage is to provide an AVT with a circuit with no leakage current to ground, so that when many AVTs are installed in a facility does not cause any issues with the power grounding system.

Another object, feature, or advantage is to provide an AVT.

Another object, feature, or advantage is to provide an AVT which does not require batteries.

A still further object, feature, or advantage is to provide an AVT which may be charged with high intensity light, inductive charging coils, or otherwise.

Yet another object, feature, or advantage is to provide an AVT which may be quickly charged through line connections.

A still further object, feature, or advantage is to provide an AVT which, once charged, can perform multiple tests before additional charging is required.

Another object, feature, or advantage is to provide an AVT, which when in a TEST mode the LED light patterns help the worker discern between “normal” and “test” state on the AVT.

Another object, feature, or advantage is to provide an AVT which enhances electrical safety.

Yet another object, feature, or advantage is to provide an AVT which may include wireless monitoring.

A further object, feature, or advantage is to provide an analog approach or hybrid-analog approach to AVT design.

A still further object, feature, or advantage to provide for requiring a continuity connection to source to illuminate voltage presence indicators.

Another object, feature, or advantage is to provide for active input current limiting to occur prior to AC being converted to DC instead of a power supply having passive components to limit the inrush current before converting.

Yet another object, feature, or advantage is to split a power supply function for a 3-phase power supply (e.g. 7.8 VAC-600 VAC) into five pieces, (4) VSLTs and a human-machine-interface (HMI) unit such that there is space to mount the HMI on an enclosure door/flange and the (4) VSLTs provides numerous mounting, installation, and termination possibilities.

According to another object, feature, or advantage power supply circuitry of an AVT also doubles as a pathway for a voltage test (e.g. 3V test) and a continuity test function which may be used for both forward and reverse continuity testing.

A further object, feature, or advantage is to provide a directional design of a number of VSLT circuits (e.g. 8 for L1, L2, L3, and GRD) which enables a continuous source conductor connection check whenever the AVT have full voltage on all 3 phases (Normal Operation). Given that AVTs have 8 leads total and use 2 leads per phase to connect to a source conductor. This dual source-connection “tests” may be performed both: 1) during the circuits normal operation which requires continuity; and 2) the test function retests it during the 3V test.

A still further object, feature, or advantage is to provide an internal floating DC Common reference which is not at GRD during normal operation, but is floating and goes to zero/GRD when there is no line voltage such that the same circuit and pathway for a 3V TEST and a Continuity TEST may be performed.

Another object, feature, or advantage is to provide a physical design which reduces harmonics/noise at the connections to voltage sources.

A still further object, feature, or advantage is to provide an AVT which uses an ultra-low leakage test verification circuit such as that disclosed in U.S. Pat. No. 11,506,602 to Clarke, hereby incorporated by reference in its entirety, with a TEST enable circuit.

Another object, feature, or advantage is to provide leads with termination and mechanical design which provides quick-error free installation of the leads.

Yet another object, feature, or advantage is to provide light indicators such as LEDs with multiple states indicative of voltages, such as a first mode of operation where the light indicators are flashed sufficiently fast in response to a detected voltage level to appear as solid-on, a second mode of operation where the light indicators are visibly flashing in response to a lesser voltage level, and a third mode of operation where the light indicators shimmer, and a fourth mode of operation where the light indicator is dim or off.

A further object, feature, or advantage is to provide light indicators with flash rates determined by an analog R-C circuit to allow for a continuum of states including high flash rates appearing as solid-on for a high voltages, lower flash rates appearing as shimmering, even lower flash rates appearing to visibly flash, and lower flash rates appearing as dim, and off.

A still further object, feature, or advantage is to pulse GRD light indicator pairs so that workers know that these light indicators are functional because, under normal power systems circumstances, the GRD LEDs do not flash.

A further object, feature, or advantage is to provide a redundant continuity test.

One or more of these and/or other objects, features, or advantages will become apparent from the specification and claims that follow. No single embodiment need include or meet each and every object, feature, or advantage as different embodiments may have different objects, features, or advantages.

According to one aspect, an absence of voltage tester (AVT) for use with a plurality of phase connections, is provided. The AVT includes a housing assembly, an input for a user to initiate a test sequence for absence of voltage testing, a supervisory test circuit, a visual indicator to confirm operation of the AVT after a test sequence has been performed using the supervisory test circuit, a secondary power source operatively connected to the supervisory test circuit for powering the supervisory test circuit, a circuit assembly for each of the plurality of phase connections configured to enable continuity testing, and a plurality of phase indication lighting elements. In a first mode of operation phase indication is provided using the plurality of phase indication lighting elements to show voltage present on each of the plurality of phase connections and continuity to each of the plurality of phase connections. In a second mode of operation in response to initiation of the test sequence for the absence of voltage testing, the test sequence tests each of the plurality of phase connections and the supervisory test circuit activates the visual indicator if continuity testing of the AVT is successful while the secondary power source is used to energize the AVT.

According to one aspect, an absence of voltage tester (AVT) for detecting absence of voltage is provided. The AVT includes a housing assembly, analog circuitry electrically connected to a power source wherein the analog circuitry is configured to detect the absence of voltage and is further configured to detect connections to the power source. The AVT may include a button, switch, or other means for a user to initiate a test for the absence of voltage. The AVT may further include a supervisory test circuit within the analog circuitry. The AVT may further include a visual indicator within the analog circuitry to confirm the absence of voltage after an absence of voltage test has been performed. The AVT may further include a secondary power source operatively connected to the supervisory test circuit for powering the supervisory test circuit. The AVT may further include a circuit assembly for each phase connection that enables both a bi-directional and/or redundant continuity test and provides a current limited and reduced voltage power supply front end to the logic circuitry.

According to one aspect, an absence of voltage tester (AVT) for use with a plurality of phase connections is provided. The AVT includes a housing assembly, means for a user to initiate a test for the absence of voltage, a supervisory test circuit, a visual indicator to confirm the absence of voltage after an absence of voltage test has been performed using the supervisory test circuit, a secondary power source operatively connected to the supervisory test circuit for powering the supervisory test circuit, a circuit assembly for each of the plurality of phase connections configured to enable both a bi-directional and redundant continuity test, and a plurality of phase indication lighting elements. In a first mode of operation phase indication is provided using the plurality of phase indication lighting elements to show voltage present on each of the plurality of phase connections and continuity to each of the plurality of phase connections. In a second mode of operation in response to initiation of the test for the absence of voltage a continuity test is performed for each of the plurality of phase connections and the supervisory test circuit is configured to activate the visual indicator if the absence of voltage is determined for all of the phase connections. The circuitry assembly for each of the plurality of phase connections may provide for current limiting and voltage reduction. The current limiting may be active current limiting.

According to another aspect, an absence of voltage tester (AVT) for detecting absence of voltage includes a housing assembly, analog circuitry electrically connected to a power source, the analog circuitry configured to detect the absence of voltage, the analog circuitry configured to detect connections to the power source. The AVT further includes means for a user to initiate a test for the absence of voltage, a supervisory test circuit within the analog circuitry, and a visual indicator within the analog circuitry to confirm the absence of voltage after an absence of voltage test has been performed. The AVT may further include a secondary power source operatively connected to the supervisory test circuit for powering the supervisory test circuit and a circuit assembly for each phase connection that enables both a bi-directional/redundant continuity test and provide a current limited and reduced voltage power supply front end. In some embodiments, the visual indicator may include a green lighting element and the analog circuitry may be configured to confirm the absence of voltage after the absence of voltage test has been performed by illuminating the green lighting element. The analog circuitry may be configured such that any voltage over a first threshold voltage is associated with voltage present and any voltage under the first threshold voltage is associated with the absence of voltage. The AVT may further include at least two lighting elements per phase of the power source and wherein the analog circuitry is configured to illuminate a first of the at least two lighting elements when a voltage of a phase is greater than a second threshold voltage and a second of the at least two lighting elements when a magnitude of the voltage is less than a magnitude of the second threshold voltage, the magnitude of the second threshold voltage greater than a magnitude of the first threshold voltage. In some embodiments, each of the at least two lighting elements per phase of the power sources is a red lighting element.

The AVT may further include a third visual indicator and wherein the analog circuitry is configured to illuminate the third visual indicator when the voltage present on any single phase or GRD is above the first threshold voltage and below a third voltage threshold. The first threshold may, for example, be about 3 volts. The third voltage threshold may be greater than a magnitude of the second threshold voltage. The third voltage threshold may be less than 50 volts. The AVT may further include a charging visual indicator within the analog circuitry and wherein the charging visual indicator is illuminated while the AVT is charging. The charging visual indicator may be illuminated while the AVT is charging. The AVT may further include a charge low visual indicator within the analog circuitry. The AVT may further include a super capacitor and the analog circuitry may be configured such that the charge low visual indicator indicates state of the super capacitor. The means for a user to initiate a test for the absence of voltage may include, without limitation, a push button or switch. The secondary power source may be a super capacitor and the analog circuitry may be is configured to charge the secondary power source such as by using line voltage from the power source, using inductive charging coils, using RF power, using a solar interface or otherwise. The analog circuitry may provide temperature compensation. The analog circuitry may include an application specific integrated circuitry (ASIC). The supervisory circuit of the AVT may be further configured to flash one or more visual indicators to indicate presence of stored energy if voltage present is over a stored energy threshold. This stored energy threshold or fourth threshold may be around 50 volts in some embodiments.

The housing assembly may include a face and wherein the visual indicator is visible at the face as a part of the human-machine interface (HMI). The power source may include a single phase, two phase, or three phase AC power source. The power source may include a DC power source. The analog circuitry may include a pair of voltage sense lead and continuity terminations for each phase of the power source. Each pair of voltage lead terminations may be coupled to a VSLT printed circuit board (PCB). The VSLT PCB may be mounted directly on conductors of the power source. The AVT may further include a heat sink mounted directly on the conductors of the power source. The housing assembly may include a door mount assembly. The AVT may be connector less other than source connections.

According to another aspect, a method of operating an absence of voltage tester (AVT) for detecting the absence of voltage associated with a power source having at least one phase, the AVT having leads for ground and each of the at least one phase is provided. The method includes monitoring of each of the at least one phase of the power source to visually indicate presence or absence of voltage on each of the at least one phase of the power source using analog circuitry and receiving input from a user to initiate a test. The method further includes initiating the test to determine absence of voltage for the power source after receiving input from the user to initiate the test. The method further includes during the test detecting connectivity of the AVT to the power source using an analog supervisory test circuit powered by a secondary power source to confirm the phase and ground leads of the AVT are in direct contact with conductors being tested and visually displaying a green indicator to confirm the absence of voltage above a first threshold after the test has been performed and the secondary power source is operative. The phase and ground leads are connected to conductors of the power source using voltage sense lead and continuity termination (VSLT) printed circuit boards. The method may be performed without software and/or microcontrollers. The analog supervisory test circuit may include an application specific integrated circuit (ASIC). The green indicator may be mounted at a door mount assembly. The analog circuitry may include power conversion circuitry at the voltage sense lead and continuity termination printed circuit boards. The method may further includes visually displaying at least one indicator for each of the at least one phase to indicate voltage is above a second threshold, the at least one indicator not being green in color. The method further include visually displaying at least one indicator indicative that voltage is below a third threshold, the third threshold greater than the second threshold, and the at least one indicator indicative that the voltage is below a third threshold not being green in color. The secondary power source may be a super capacitor. The method may further include visually indicating that the secondary power source is charging. The method may further include conducting heat from the voltage sense lead and continuity termination printed circuit boards to the conductors.

According to another aspect, an absence of voltage tester (AVT) for detecting absence of voltage includes a housing assembly, circuitry electrically connected to a power source, the circuitry configured to detect the absence of voltage, the circuitry configured to test for connectivity to the power source, means for a user to initiate a test for the absence of voltage, a supervisory test circuit within the circuitry to verify that the AVT is functioning properly, and a set of visual indicators which include a first visual indicator to confirm the absence of voltage after an absence of voltage test has been performed, a second visual indicator to display voltage presence between a first threshold and a second threshold, and a set of visual indicators to display positive or negative voltage on each line of the power source when line voltage is present. A secondary power source is operatively connected to the supervisory test circuit for powering the supervisory test circuit. The first threshold may be about 3 volts The second threshold may be between 3-20 volts. The set of visual indicators may illuminate during testing where voltage is present. Each of the set of visual indicators may be a red LED. The second visual indicator may be a yellow LED. The AVT may further include a low charge visual indicator which is configured to illuminate based on charge level associated with the secondary power source. The low charge visual indicator may be an orange LED. The AVT may further include a charging visual indicator which is configured to illuminate (such as continuously or flashing) while the secondary power source is charging. The charging visual indicator may be a blue LED. The AVT may further include a means for a user to initiate the test for the absence of voltage such as a switch or button or magnetic switch which may be positioned at a face of the AVT for locating at a panel. The first visual indicator, the second visual indicator, and the set of visual indicators may be positioned on a face of the AVT. The means for the user to initiate the test may be positioned at the face of the AVT. The AVT may further include voltage sensing lead and continuity terminations operatively connected to conductors of the power source. The voltage sensing lead and continuity terminations may include printed circuit boards (PCBs). There may be a printed circuit board for each phase of the power source with two conductors. Each of the printed circuit boards may be positioned rearward of the housing assembly. The first visual indicator, the second visual indicator, and the set of visual indicators to display positive or negative voltage on each line of the power source may each include at least one LED. The AVT may further include a charging interface operatively connected to the secondary power source The charging interface may be a solar interface, may be an inductive charging interface, may include a photodiode, may be an RF-powered interface, or other type of charging interface.

According to another aspect, a method for performing testing of a power source with an absence of voltage tester (AVT) is provided. The method includes receiving input from a user to initiate a test, initiating the test to determine absence of voltage for the power source after receiving the input from the user to initiate the test, performing voltage measurement testing for each phase of the power source, during the voltage measurement testing showing visual indicators that the testing is performed, visually displaying at a face of the absence of voltage tester a green indicator to confirm the absence of voltage above a first threshold after the voltage measurement testing, visually displaying at the face of the absence of voltage tester indicators of voltage at each phase of the power source having a magnitude greater than a second threshold, and visually displaying at the face of the absence of voltage tester an indicator that voltage present is between the first threshold and a third threshold. The green indicator may include an illuminated LED and the green indicator may include one or more green LEDs. The step of visually displaying at the face of the absence of voltage tester indicators of voltage at each phase of the power source may be performed using red illumination such as by using red LEDs. The step of visually displaying at the face of the absence of voltage the indicator that voltage present may be between the first threshold and a third threshold is performed using yellow illumination. The yellow illumination may be performed using a yellow LED The method may further include flashing the indicators of voltage at each phase of the power source during the voltage measurement testing. The method may further include visually displaying at the face of the absence of voltage tester a charging indicator. The charging indicator may include a flashing blue LED to indicate that the absence of voltage tester is charging. The method may further include visually displaying at the face of the absence of voltage tester a charge low indicator. The charge low indicator may include an illuminated orange LED. The step of receiving the input from the user to initiate the test may include receiving a signal from a switch mounted at a face of the absence of voltage tester. The switch may be a push button switch, a magnetic switch, or another type of switch or other means.

According to another aspect, an absence of voltage tester (AVT) for detecting the absence of voltage associated with a power source is provided. The AVT includes a panel mount assembly, circuitry at the panel mount assembly for detecting presence of voltage, a supervisory test circuit within the circuitry for performing testing, a power supply conversion circuit, and separate VSLT assembly modules for each phase of the power supply conversion circuit. The power supply conversion circuit may be physically distributed between the circuitry at the panel mount assembly and the separate VSLT assembly modules. Each of the separate VSLT assembly modules may include two voltage sensing lead and continuity terminations. Each of the separate VSLT assembly modules may include two voltage sensing lead and continuity terminations for physical connection with a load source conductor of the power source Each of the separate VSLT assembly modules may include a first voltage sensing lead and continuity termination printed circuit board and a second voltage sense lead and continuity termination (VSLT) printed circuit board. Each VSLT may be configured to rectify half of a sine wave signal on the load source conductor. The load source conductor may include at least one of a wire, a lug, a fuse block, an isolator, a circuit breaker, and a busbar. The load source conductor may further include a heat sink. The separate VSLT assembly modules may be integrated into a fused disconnect switch, a circuit breaker, an isolation switch, a disconnect or knife switch without fuse, or a galvanically isolated air gap device. The separate VSLT assembly modules may be remote from the panel mount assembly The AVT may include a protective wrap configured to protect the separate VSLT assembly modules. The AVT may be configured for installation by inserting the protective wrap and the separate VSLT assembly modules disposed therein through a hole in a panel.

According to another aspect, a power supply conversion circuit includes a plurality of separate VSLT assembly modules, one of the plurality of separate VSLT assembly modules for each phase of the power supply conversion circuit, wherein each of the separate VSLT assembly modules comprises a first voltage sense lead and continuity termination (VSLT) printed circuit board and a second voltage sense lead and continuity termination (VSLT) printed circuit board and wherein the first VSLT PCB is electrically connected to a source conductor for the phase at a first VTL connection point and wherein the second VSLT PCB is electrically connected to the source conductor for the phase at a second VTL connection point and a conductive bridge of the source conductor extends between the first VTL connection point and the second VTL connection point The power supply conversion circuit further includes circuitry at a panel mount assembly electrically connected to each of the plurality of separate VSLT assembly modules. Each VSLT may be configured to rectify half of a sine wave signal on the source conductor. Each of the plurality of separate VSLT assembly modules may be integrated into an isolator. The source conductor may be a heat sink. The circuitry at the panel mount assembly may be electrically connected to each of the plurality of the separate VSLT assembly modules using wiring of a smaller gauge sufficient for current limited signals from each of the plurality of the separate VSLT assembly modules. The wiring may be twisted pair wiring. The plurality of separate VSLT assembly modules may be positioned within protective wrap. The plurality of separate VSLT assembly modules may include four separate VSLT assembly modules, each of the four separate VSLT assembly modules may include two VSLT circuits.

According to another aspect, a voltage sense lead and continuity termination (VSLT) assembly module for use with a source conductor of a power source is provided. The VSLT assembly module includes a first voltage sense lead and continuity termination (VSLT) circuit, and a second voltage sense lead and continuity termination (VSLT) circuit. The first VSLT circuit may be electrically connected to the source conductor for a phase of the power source at a first voltage termination lead (VTL) connection point. The second VSLT circuit may be electrically connected to the source conductor for the phase of the power source at a second voltage termination lead (VTL) connection point. The first VTL connection point and the second VTL connection point may be positioned at the source conductor such that a conductive bridge of the source conductor extends between the first VTL connection point and the second VTL connection point. The first VSLT circuit may perform half wave rectification of a signal on the source conductor. The second VSLT circuit may perform half wave rectification of the signal on the source conductor. The VSLT assembly module may be configured to generate a signal which enables current flow for a voltage presence function of an absence of voltage tester (AVT) A first connection between the first VSLT circuit and the source conductor may be made directly on the VSLT assembly module. A second connection between the second VSLT circuit and the source conductor may be made directly on the VSLT assembly module. In some embodiments, the system may include a plurality of the VSLT assembly modules enclosed within a protective wrap along with wiring between each of the VSLT assembly modules and a panel mount assembly. In some embodiments, a system may include a plurality of the VSLT assembly modules mechanically connected together. The plurality of the VSLT assembly modules may be mechanically connected together by snapping or ganging. In some embodiments a system may include a plurality of the VSLT assembly modules where the plurality of the VSLT assembly modules include a L1 VSLT assembly module for use with an L1 source conductor, a L2 VSLT assembly module for use with an L2 source conductor, a L3 VSLT assembly module for use with an L3 source conductor, and a GND power conversion module for sue with a GND source conductor Each of the 8 leads present may terminate in an error-free manner with its own separate location to provide proper dual lead termination performed correctly.

According to another aspect, an absence of voltage tester (AVT) for detecting absence of voltage includes a housing assembly, analog circuitry electrically connected to a power source, the analog circuitry configured to detect the absence of voltage, the analog circuitry configured to test for connectivity to the power source, means for a user to initiate a test for the absence of voltage, a supervisory test circuit within the analog circuitry, a visual indicator operatively connected to the supervisory test circuit to confirm the absence of voltage after an absence of voltage test has been performed, a secondary power source operatively connected to the supervisory test circuit for powering the supervisory test circuit. The analog circuitry may include a sample and hold circuit. The AVT may be configured to reduce or eliminate leakage of current to ground by the analog circuitry. The analog circuitry may be configured to perform the test and illuminate the visual indicator in under 1 second, under 1.5 seconds, under 2 seconds, under 3 seconds, under 4 seconds, under 5 seconds or another short time from the user initiating the test using the means for the user to initiate the test. The visual indicator may be illuminated by providing a pulsing signal to an LED In a first mode of operation phase indication is provided using a plurality of phase indication lighting elements to show voltage present on each of a plurality of phase connections and continuity to each of the plurality of phase connections. In a second mode of operation in response to initiation of the test for the absence of voltage a continuity test is performed for each of the plurality of phase connections and the supervisory test circuit is configured to activate the visual indicator if the absence of voltage is determined for all of the phase connections. In some embodiments, the continuity test is a bi-directional continuity test. A circuitry assembly for each of the plurality of phase connections may provide for current limiting and voltage reduction. The current limiting may be active current limiting. The active current limiting may occur prior to conversion to DC.

According to another aspect, an absence of voltage tester (AVT) for detecting absence of voltage includes a housing assembly, analog circuitry electrically connected to a power source, the analog circuitry configured to detect the absence of voltage, the analog circuitry configured to detect connections to the power source, means for a user to initiate a test for the absence of voltage, a supervisory test circuit within the analog circuitry, a redundant supervisory test circuit within the analog circuitry, a visual indicator within the analog circuitry to confirm the absence of voltage after an absence of voltage test has been performed with the supervisory test circuit, a redundant visual indicator within the analog circuitry to confirm the absence of voltage after the absence of voltage test has been performed with the redundant supervisory circuit, a secondary power source operatively connected to the supervisory test circuit for powering the supervisory test circuit, and a circuit assembly for each phase connection that enables both a continuity test and provide a current limited and reduced voltage power supply front end. The visual indicator may include a first green lighting element and wherein the analog circuitry is configured to confirm the absence of voltage after the absence of voltage test has been performed by illuminating the first green lighting element.

According to another aspect, an absence of voltage tester (AVT) for detecting the absence of voltage associated with a power source, the AVT includes a panel mount assembly, circuitry at the panel mount assembly for detecting presence of voltage, a supervisory test circuit within the circuitry for performing testing, a power supply conversion circuit, separate VSLT assembly modules for each phase of the power supply conversion circuit. The power supply conversion circuit is physically distributed between the circuitry at the panel mount assembly and the separate VSLT assembly modules. The VSLT assembly modules each comprise dual stabs for connection with a corresponding source connector.

### BRIEF DESCRIPTION OF THE FIGURES

FIG. 1 is an absence of voltage tester (AVT).

FIG. 2 illustrates another view of the AVT with lead wire terminations to VSLT modules

FIG. 3 illustrates the continuity-dependent voltage presence operation of the AVT.

FIG. 4 illustrates a representative example of the mounting of the VSLT modules.

FIG. 5 illustrates another example of the mounting of the VSLT modules.

FIG. 6 illustrates another view of the AVT during the installation process.

FIG. 7 illustrates the AVT after the installation process with the mounting nut positioned against the panel in an installed position to provide a connector-less design.

FIG. 8A illustrates one example of the face of the AVT including visual indicators.

FIG. 8B illustrates the face of the AVT including visual indicators.

FIG. 9 illustrates various conditions which may be determined from the visual indicators.

FIG. 10 is a block diagram illustrating normal operation of the AVT where continuity to source conductors is required for phase indication.

FIG. 11 is a block diagram illustrating test operation for a continuity test.

FIG. 12 illustrates a VSLT module or assembly with a VSLT-A circuit and a VSLT-B circuit, both electrically connected to an L1 conductor.

FIG. 13 illustrates (4) VSLT modules or assemblies, each with two VSLT circuits, one VSLT assembly for each of L1, L2, L3, and GND.

FIG. 14 is a block diagram for circuitry of an AVT.

FIG. 15 is an example of a VSLT module for a source conductor (such as L1, L2, L3, or GND) which is a different example from FIG. 12.

FIG. 16 is an example of a power circuit which may form a part of the AVT.

FIG. 17 illustrates VSLT modules with lead wires to source conductors.

FIG. 18 illustrates an AVT with dual stabs used for connection with source conductors.

FIG. 19A, FIG. 19B, FIG. 19C, and FIG. 19D illustrate a VSLT module with dual stabs used to connect with a source conductor.

FIG. 20 illustrates an example of operation of the AVT in both an idle state and a test state.

### DETAILED DESCRIPTION

Although various structures, functions, and features are discussed with respect to particular embodiments of electrical safety devices, and especially AVTs, it is to be understood that different embodiments may have different features or combinations of features, and not every feature need be present in every embodiment. In addition, it is to be understood that some embodiments are directed towards power supplies which may have any number of applications in electrical safety devices or otherwise.

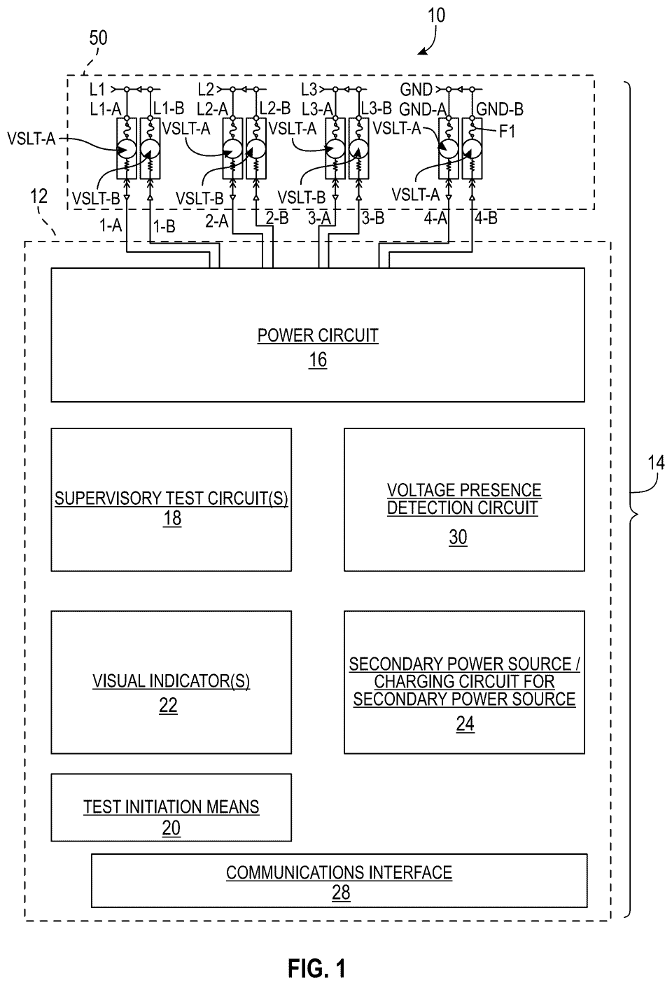

FIG. 1 illustrates an absence of voltage tester (AVT) 10 for detecting absence of voltage. The particular example shown is configured for use with 3-phase power source with L1, L2, L3, and GND power source conductors. The AVT includes a housing assembly 12. Note that not all components of the AVT 10 are disposed within the housing assembly 12 as a plurality 50 of separate VSLT assembly modules are present which are not within the housing assembly 12 as will be explained in more detail. The housing assembly 12 may be panel mounted.

The AVT 10 includes analog circuitry 14. The analog circuitry 14 includes a power circuitry 16 which is electrically connected to the power source through a plurality 50 of separate VSLT assembly modules.

The analog circuitry 14 includes circuitry configured to detect the presence of absence of voltage on each phase of the power source. The analog circuitry 14 further includes a supervisory test circuit 18. The supervisory test circuit 18 may be used to verify that the AVT is functioning property, such as by ensuring continuity of the AVT before and/or after a voltage test The use of analog circuitry allows for no software such as with microcontrollers while also providing hardwired reliability. In some embodiments, the analog circuitry may be integrated into an application specific integrated circuitry (ASIC). The analog circuitry 14 may be a low power discrete analog design such as 0.5 mA of power.

A secondary power source 24 is shown which may have a charging circuit for the secondary power source. The secondary power source 24 may be a super capacitor. The charging circuit may provide for charging the super capacitor. In some embodiments, the super capacitor may be charged by the power source when the power source is in normal working state and before it is disconnected. The super capacitor should have sufficient charge to run the absence of voltage test multiple times. It is preferred, however, that the super capacitor is not larger than necessary to store sufficient charge to run a desired number of absence of voltage tests as for safety reasons, it is not desirable to store too large of charge. Although batteries may be used, this is not preferred for a variety of reasons. Importantly, supercapacitors are generally safer than rechargeable batteries with less risk of leakage or fire. Super capacitors generally have a higher power density than rechargeable batteries. Super capacitors tend to have a much longer cycle life than rechargeable batteries. Super capacitors have higher charge and discharge efficiencies. Super capacitors have better temperature performance. Thus, for safety reasons and space constraints, super capacitors are generally preferable. Where the AVT 10 is analog circuitry, less charge is required than in alternatives such as those which use microcontrollers and have higher current requirements thus the super capacitor may be charged more quickly to a level of charge needed to ensure the ability to provide a certain number of tests than if non-analog circuitry was used in performing the test. In addition, the super capacitor may be smaller in size where there are lessened stored charge requirements.

In some embodiments, the charging circuit for the secondary power source may be charged using a solar interface or through the use of inductor charging coils, via RF power, or otherwise For example, in some embodiments light from a mobile phone may be received at the solar interface and charge the secondary power source sufficiently that it may be used to perform the absence of voltage testing.

The supervisory test circuit 18 may be of the type which meets UL 1436 standards (hereby incorporated by reference). The supervisor test circuit 18 is used to verify that the absence of voltage tester is functioning properly and uses the secondary power source. The supervisory test circuit 18 may be used to verify that the tester is functioning properly before and after voltage measurements are performed.

One or more visual indicators 22 may be present such that results of a test may be communicated to a user. In some embodiments, such as where the AVT 10 is configured to meet UL 1436 standards, the visual indicators 22 may include a visual indicator which illuminates to green to indicate that there is an absence of voltage. According to the standard, the visual indicator shall only illuminate green when all phase-to-phase and phase-to-ground voltages are <3.0 Vac rms or <3.0 Vdc. In addition, the visual indicator shall not illuminate green unless the phase and ground leads are in direct contact with the circuit conductors being tested; when a phase lead is connected to ground or the ground lead is connected to a phase conductor the visual indicator shall not illuminate green; and the visual indicator shall not illuminate green unless the secondary power source is operational.

The AVT may include additional indicators such as indicators which flash during the test, indicators which indicate on which of the phase or ground conductors' voltage is present, indicators which indicate different thresholds of voltage present, as well as indicators which indicate that the charge for the secondary power source is low, or that the secondary power source is charging.

A test initiation means 20 is shown. The test initiation means may be in the form of a switch such as a push button switch, a slide switch, a rocker switch, a touch switch, an optical switch, a reed switch, a magnetic switch, or other type of switch. The test initiation means 20 is used by a user to initiate a test to determine absence of voltage by the AVT.

The AVT may be SIL3 rated. In some embodiments there may be more than one supervisory test circuit 18. There may also be more than one visual indicator (such as a green LED) to indicate the results of the absence of voltage test. Where more than one supervisory test circuit is used, it may be referred to as redundant. Where more than one visual indicator is used to indicate the results of the absence of voltage test, it may be referred to as redundant.

A communications interface 28 is also shown. The communications interface 28 may provide for communicating results of an absence of voltage testing to a remote location such as over a network or to a local device. The communications interface 28 may be a wired or wireless interface such as a serial interface, a network interface, a USB interface, a Controller Area Network (CAN) interface, a Modbus interface, a Wi-Fi interface, a Bluetooth interface, a Zigbee interface, a cellular network interface, an industrial wireless local area network (WLAN), or other type of interface.

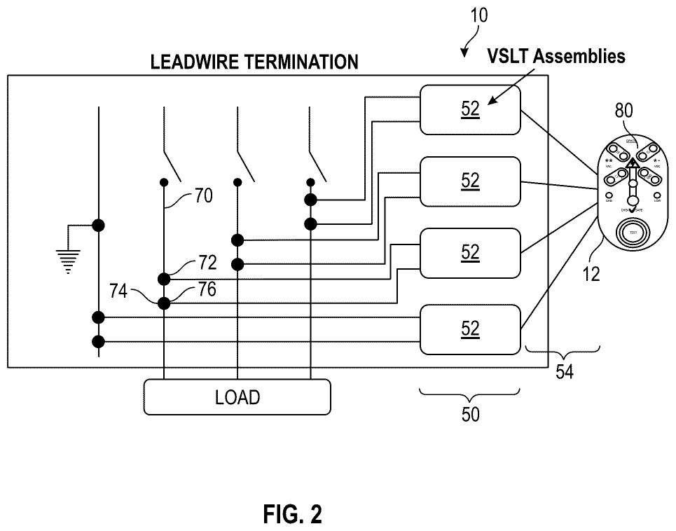

FIG. 2 illustrates another view of the AVT 10. The AVT 10 has a housing assembly 12 which may be connected through a panel. For example, in some embodiments, a 30 mm hole may be made in the panel door and the face 80 of the panel assembly may then be viewed from outside of the enclosure so that a user may perform absence of voltage testing without opening the enclosure. The AVT also has a plurality 50 of separate VSLT assembly modules 52, one for each of the lines L1, L2, L3, GND of the power source. An isolator may be present for each of these lines. Each of the VSLT assembly modules 52 has two connections to a corresponding one of the lines of the power source. Wiring 54 is shown from the VSLT assembly modules 52 to the circuitry within the housing assembly 12.

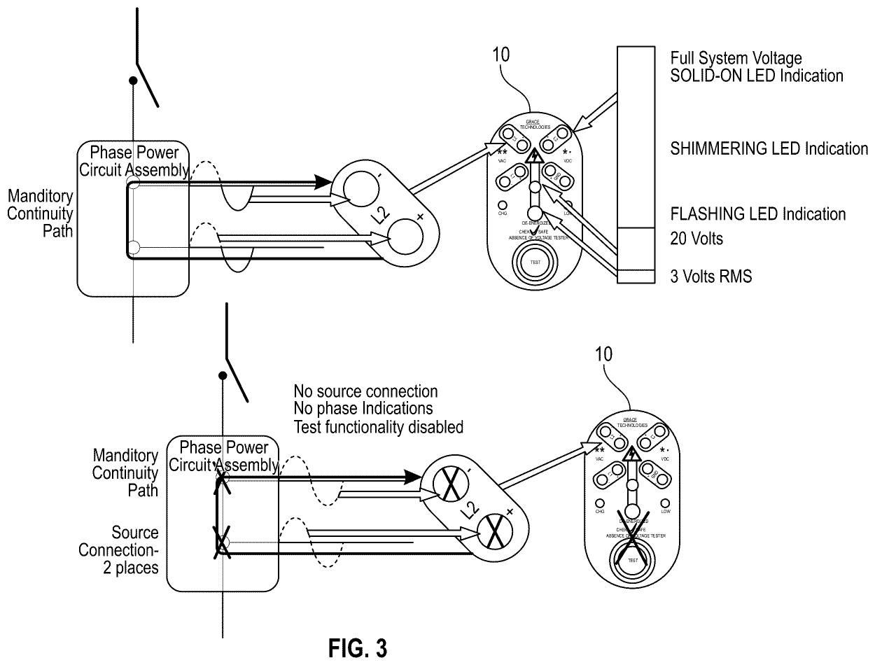

FIG. 3 illustrates different modes of operation for the AVT 10. In the phase power circuit assembly there is a mandatory continuity path with a source connection in two different places. Thus, continuity is confirmed. In addition, the AVT confirms state for each phase through illumination of corresponding positive and negative voltages indicators for each phase. The L2 phase is shown which is on the face of the AVT 100. If there is no source connection then there is no phase indications and test functionality is disabled. Thus continuity determination is redundant.

FIG. 3 illustrates an example of operation of one example of an AVT where the voltage indicating circuit has flash rates which are directly proportional to input voltages. For example, especially where analog circuitry is used, a voltage-dependent RC network may be used. Thus, at a first threshold (e.g. 330V), the LEDs flash so quickly they are perceived as a solid on indication. Above a second threshold (e.g. 160V) but less than the first threshold, the LEDs flash at a slower rate so as to be perceived as a shimmer. Below a third threshold (e.g. 20V), the LEDs appears to be dim or off. This information provides a worker with additional information regarding voltage present. For example, this may be used to show that stored energy is bleeding down after an isolator is open and the worker may observe the transitions from solid on, to shimmering, to flashing, to off. The ranges set forth are merely examples, it is to be understand that different ranges may be present as may be appropriate for a particular application. It should further be understood that although RC circuit may be used, other timing circuits may be used to vary the flash rate. Where digital circuits are used pulse rate may be controlled digitally or pulse width modulation may be used.

As shown in FIG. 3, one of a plurality of phase connections (L2) is shown with two corresponding voltage indicators which may be LEDs. In operation, a solid on indicates a full system voltage. A shimmering LED indicates a voltage less than a solid-on. A flashing LED indicates a voltage less than shimmering. A dim or off LED indicates less voltage. A separate indicator may be used to indicate less than 20 volts on all phases being monitored and a further indicator may indicate less than 3 volts RMS on any phase. Thus, the user interface of the AVT is highly advantageous as it may be used to implement absence of voltage testing in a clear manner to provide feedback regarding where voltage is present as well as some information regarding the magnitude.

Thus, for example, as shown in FIG. 3 there may be at least four different voltage level thresholds associated with the functionality of the AVT. An upper threshold is associated with a high voltage level and may be indicated by a sold-on indicator. Another threshold may indicate that there is stored charge present which may be indicated by a shimmering indicator or a flashing indicator. For example, the threshold may be set at 50 volts. Another threshold may be indicated such as by a separate indicator to include less than the threshold which may be around 20 volts. A final threshold may be set at a very low voltage level such as 3 volts and less than this threshold may be used to indicate little or no voltage present.

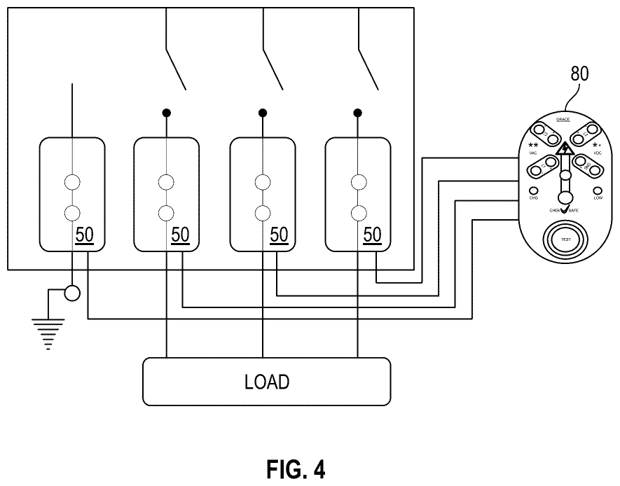

FIG. 4 illustrates a VSLT assembly module in more detail. The VSLT assembly module may including a plurality of VSLT circuits 50, where each is electrically connected to a source conductor 70. Each VSLT module 50 is connected to the source conductor 70 at a first voltage termination lead (VTL) connection point 72 and a second voltage termination lead (VTL) connection point 74. There is a conductive bridge 76 of the source conductor 70 which extends between the first VLT connection point 72 and the second VLT connection point 74.

The VSLT assembly module includes a first voltage sense lead and continuity termination (VSLT) circuit and the second VSLT circuit. The first VSLT circuit is electrically connected to the source conductor for a phase of the power source at the first voltage termination lead (VTL) connection point. The second VSLT circuit is electrically connected to the source conductor for the phase of the power source at a second voltage termination lead (VTL) connection point. Thus, for three-phase power there are four source conductors (L1, L2, L3, GND), there would be four VSLT circuits and each of the VSLT assembly modules 50 includes two VSLT circuits thus there would be a total of eight VSLT circuits present. Each VSLT circuit may be configured to perform half wave rectification of a sine wave signal on the source conductor 70. Each VSLT module may have a separate printed circuit board and may be mounted or mechanically connected to the source conductor.

The AVT verifies that is voltage sensing circuitry confirms that both voltage sensing leads (two per phase) are physically connected to the current carrying load conductions. This configuration allows the AVT to disable both normal operation and test function

Thus, the main power supply design may be considered to be distributed, partially on the VSLT assembly modules 50 which each may have its own printed circuit board and partially within the housing. Note that where analog circuitry is of a low power discrete analog design such as using 0.5 mA of power, the main power supply conversion circuit may be very small especially relative to AVTs which use micro-processors. Thus the AVT may be sufficiently small to install in tight spaces and no panel space is needed.

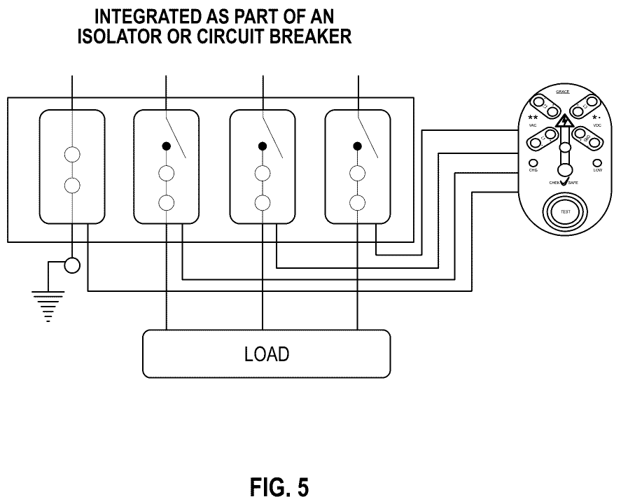

FIG. 4 and FIG. 5 illustrate representative examples of the mounting of the VSLT assembly modules 50. Note that the VSLT assembly modules 50 need not be in the housing assembly of the AVT but may be located further away from the panel. Each of the VSLT assembly modules 50 may be mounted directly on a conductor as shown in FIG. 4. Alternatively, each of the VSLT assembly modules may be mounted directly onto isolators such as disconnect switches, load break switches, safety switches, circuit breakers, enclosed safety switches, or other types of isolators as shown in FIG. 5. The VSLT boards may be mounted directly onto the conductors, lugs, busbars, fuse blocks, circuit breakers, power distribution blocks, or any internal current carrying device. The conductors may act as a heat sink for the power conversion aspect of the circuit

In a three-phase configuration there are 8 leads and preferably the termination and VSLT mechanical design to insure quick-error free installation of the 8 leads. Note that each of the 8 leads may be properly terminated independent as opposed to having both leads within a pair of leads terminate at the same location. Examples of types termination include, without limitation STA-KON connectors with a crimp design, friction fit connectors, pressure fit connectors, pre-terminated mechanical assemblies that make both source connections at one time, insulation displacement connections, direct #14 AWG to conductor connections, bolted connections, welded connections, soldered connections, friction fit connectors, wired tied to conductors and VSLTs, an interlocking assembly for all VSLTs in order to become a single integrated unit.

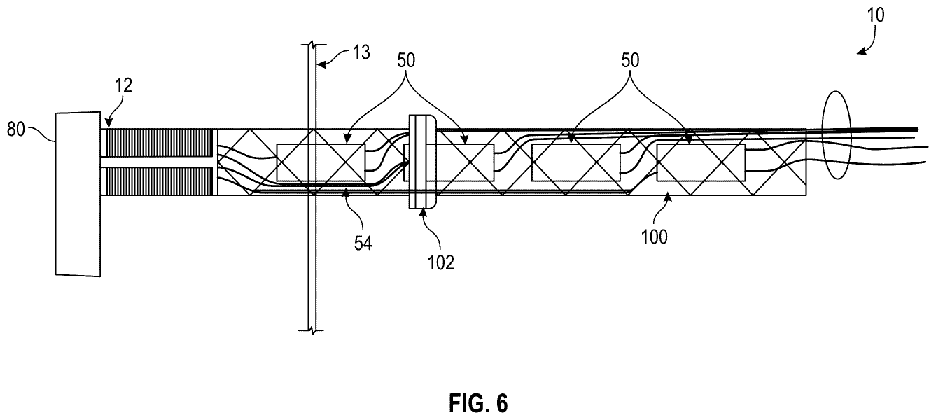

FIG. 6 illustrates another view of the AVT 10 during the installation process Note that in FIG. 6 there are four different VSLT assembly modules 50 present A protective wrap 100 is shown in which each of the VSLT assembly modules 50 is positioned along with the wiring from the source conductors to each of the VSLT assembly modules 50 as well as the wiring 54 from each of the VSLT assembly modules 50 to the housing 12 of the AVT. A mounting nut 102 is shown. Note that the AVT 10 provides a connectionless assembly. Once there is a suitable hole in the panel such as a 30 mm hole, the AVT may be inserted through the hole, the mounting nut 102 positioned and the lead wires to the voltage lines connected.

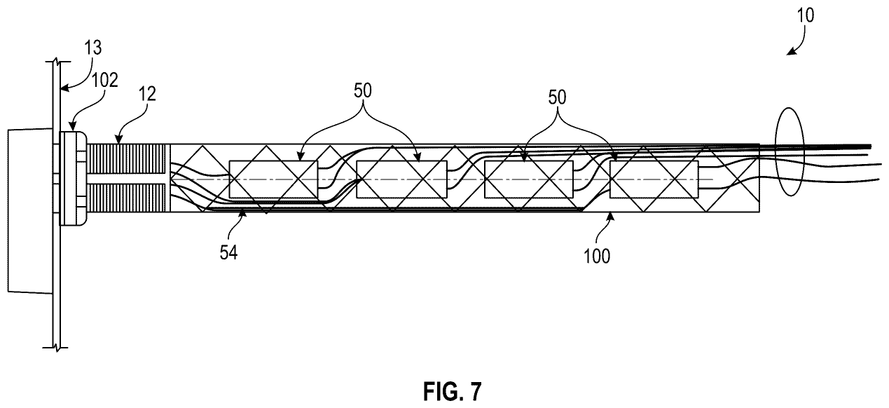

FIG. 7 illustrates the AVT 10 after the installation process with the mounting nut positioned against the panel 13 in an installed position. Note that the AVT thus has a connector-less design with all of the wired VSLT PCBs as a single assembly.

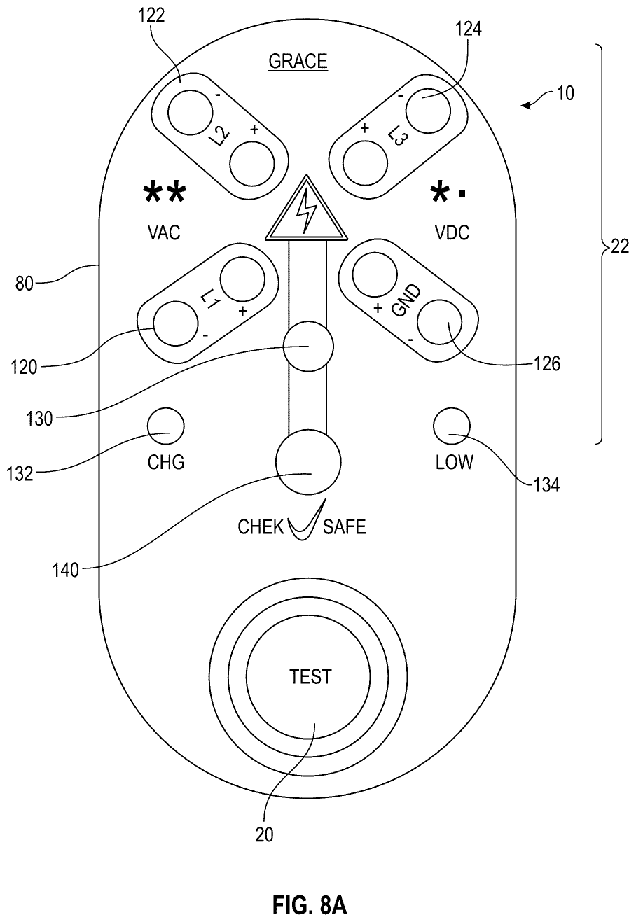

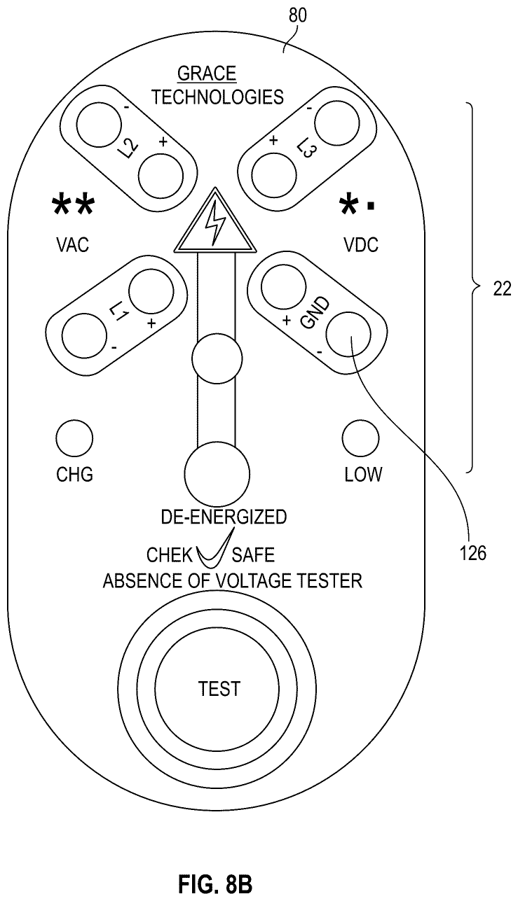

FIG. 8A illustrates the face 80 of the AVT 10 including visual indicators 22. There is a plurality of sets of visual indicators 120, 122, 124, 126 which may be in the form of lighting elements such as LEDs. As shown a first set of visual indicators 120 is associated with L1, a second set of visual indicators 122 is associated with L2, and a third set of visual indicators 124 is associated with L3, and a fourth set of visual indicators 126 is associated with GND. Each of the sets of visual indicators 120, 122, 124, 126.

The visual indicators in the sets 120, 122, 124, 126 may be red lighting elements such as red LEDs. They may be configured to flash to indicate voltage presence in the manner of a voltage indicator and thus are sometimes referred to collectively as voltage indicator lights.

A visual indicator 140 which is a lighting element such as a green LED is shown. The visual indicator may be a dual LED in order to provide redundance. The visual indicator 140 may be used to confirm the absence of voltage above a first threshold after the voltage measurement testing such as in a manner consistent with the UL-1436 specification. The first threshold may be at a low voltage such as 3V.

The visual indicator 130 may be a different color such as yellow and may be a lighting element such as an LED. This visual indicator 130 may be used to indicate that there is a voltage of more than the first threshold (e.g. more than 3v) and no input discontinuity. Thus continuity testing is redundant.

FIG. 8B illustrates another example of the face 80 of the AVT 10. FIG. 8B is similar to FIG. 8A but provides additional functionality. In particular, the GND visual indicators 160 may be used to visually display a heartbeat pulse. For example, the GND visual indicators may pulse for 100 ms every 2 seconds or for other suitable durations and frequencies. This pulsing of the GRD visual indicators conveys to a worker that these visual indicators (such as LEDs) are functional and not burned out. In addition, these LEDs may be of a different color than other visual indicators associated with other lines. For example, these GRD visual indicators may be yellow as opposed to red.

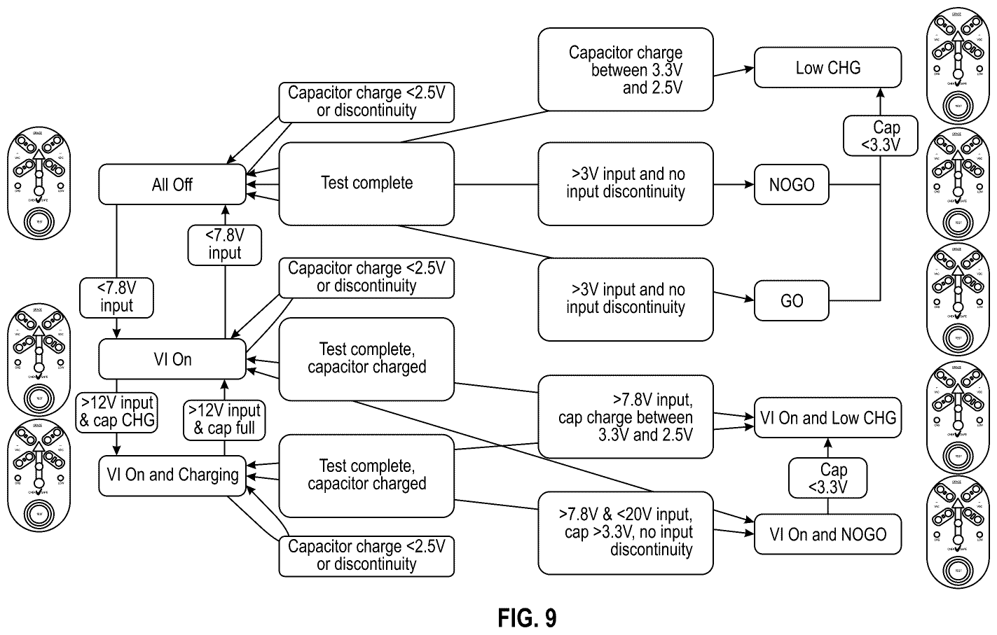

FIG. 9 further illustrates different states for different lighting elements and the correspondence to different conditions. Conditions include: (1) all lighting elements being off; (2) the voltage indicator lighting elements being on; (3) the voltage indicator lighting elements on and the device is charging; (4) a low charge voltage indicator; (5) a no go (potentially hazardous) condition; (6) a go condition where there is less than about 3 volts (or other threshold) and no input discontinuity; (7) the voltage indicator on and a low charge is present; and (8) the voltage indicator is on and a no go (potentially hazardous) condition.

All lighting elements being off (“All off”). When all lighting elements are off this is indicative that the secondary power source (e.g. super capacitor) has a low charge (e.g. less than 2.5 v) or there is a discontinuity present.

Voltage indicator lighting elements being on (“VI On”). When the voltage indicator lights are on indicating the presence of line voltage at a threshold needed to light the voltage indicator lights. In one example, this may be a threshold of greater than about 7.8 volts.

Voltage indicator lighting elements on and the device is charging (“VI On and Charging”). Indicating that there is the presence of line voltage of more than a threshold needed to light the lights and charge the super capacitor or other secondary power source. In one example, this may indicate a threshold voltage of greater than about 12 volts. The visual indicator associated with the charging may flash.

Low charge visual indicator (“Low CHG”). This may indicate that the charge for the super capacitor or other secondary power source is less than a threshold such as 3.3 volts. The visual indicator associated with low charge may flash.

No go (potentially hazardous) condition (“NOGO)”). This may indicate greater than a first threshold, such as 3 volts input and no input discontinuity. The visual indicator may flash.

Go condition where there is less than about 3 volts (or other threshold) and no input discontinuity (“GO”). This indicates a safe condition, for example, the safe condition consistently associated with UL-1436 in that the voltage present is below the first threshold such as 3 volts and there is no input discontinuity.

Voltage indicator on and a low charge is present (“VI On and Low CHG”). The visual indicator for the low charge may flash to indicate the voltage of the super capacitor or other secondary power source is below a threshold desired or required to run tests. In addition, the voltage indicator may be on to indicate presence of voltage on the line inputs.

Voltage indicator is on and a no go (potentially hazardous) condition (“VI On and NOGO”). Here, the voltage indicator may be on indicating presence of voltage and a visual indicator is also on which is associated with another threshold. In one example, the lighting of the voltage indicator indicates a voltage of at least 7.8 volts and the lighting of the other visual indicator indicates a voltage of less than 20 volts and there is no input discontinuity.

Thus, the face of the AVT provides a significant amount of information to a user performing a test regarding the condition of the AVT.

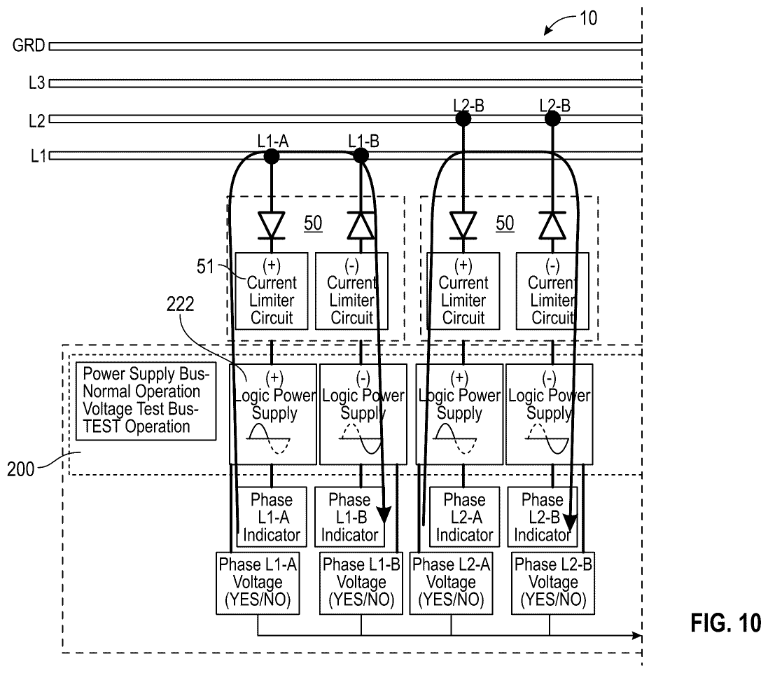

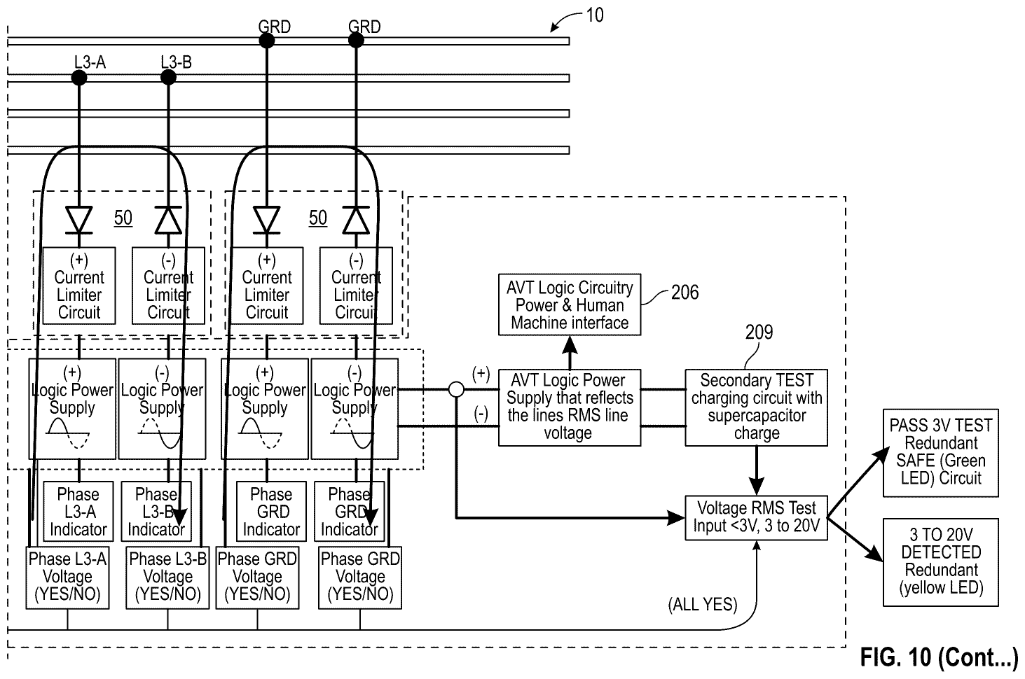

FIG. 10 is a block diagram illustrating phase indicator dependent continuity circuit and a 3 volt RMS test. The AVT 10 is shown. There are a plurality of VSLT assembly modules 50 with each of the VST assembly modules 50 electrically connected to one of the input lines L1, L2, L3, GRD. Each of the VSLT assembly modules 50 have two connections to the corresponding input line. Power circuitry includes a power supply bus which includes logic power supplies. The phase indicators are shown for both positive and negative sides of the circuit. In normal operation, the phase indicators indicate voltage present (positive or negative) on each of the input lines.

In order for phase indication to occur there must be continuity to the source conductors. In FIG. 10, current may flow from a first connection on the source conductor (e.g. L1-A), through the source conductor (e.g. L1-B), through the corresponding VSLT assembly module 50, through the corresponding logic power supply and voltage indicators. Thus, if in normal operation there is only phase indication if there is continuity to the source conductors.

Also, as shown in FIG. 10, note the placement of the current limiter circuits 51 within the VST assembly modules 50. This provides active input current limiting. This same configuration may also be used in power supplies where AC voltage is converted to DC as will be discussed later herein. Here, the current limiter circuits 51 are electrically connected to the logic power supplies 222 which are a part of what the circuitry 200 which functions as the power supply bus during normal operation and the voltage test bus during a TEST operation. Phase indicators are shown, with a phase indicator for each of the positive and negative sides of the signal from the source conductors (L1, L2, L3, GRD).

The power supply bus 200 is shown which functions as a power supply bus during operation but functions as a voltage test bus during test operation There is a logic power supply circuitry 222 either positive or negative associated with each VSLT circuit, thus one of each for each VSLT module SO.

In some embodiments a communications interface may be used. The communications interface may allow for any number of different types of communications. For example, in some embodiments, the communications interface may be a Wi-Fi interface for Wi-Fi communications, although any number of other communications including wire interfaces such as ethernet, USB, serial interfaces, wireless interfaces such as Bluetooth, Zigbee, Z-wave, cellular interfaces, optical interfaces, specialized or industrial interfaces such as CAN (Controller Area Network), Modbus, PROFIBUS, ethernet, mesh network interfaces, or other types of interfaces. In some embodiments, additional power conditioning may be performed in order to power the communications interfaces

Also shown in FIG. 10 is a circuitry for determining if voltage RMS test input is less than 3V or between 3V and 20V to provide the functionality previously described There is also circuitry 206 which is AVT logic circuitry for providing a power and human interface. There is also a secondary test circuit power logic, charging and storage circuitry 209. There is also redundant circuitry associated with safety such as may be provided with redundant LEDs. Note that in FIG. 10 under normal operation continuity to source conductors is required for phase indication to be present.

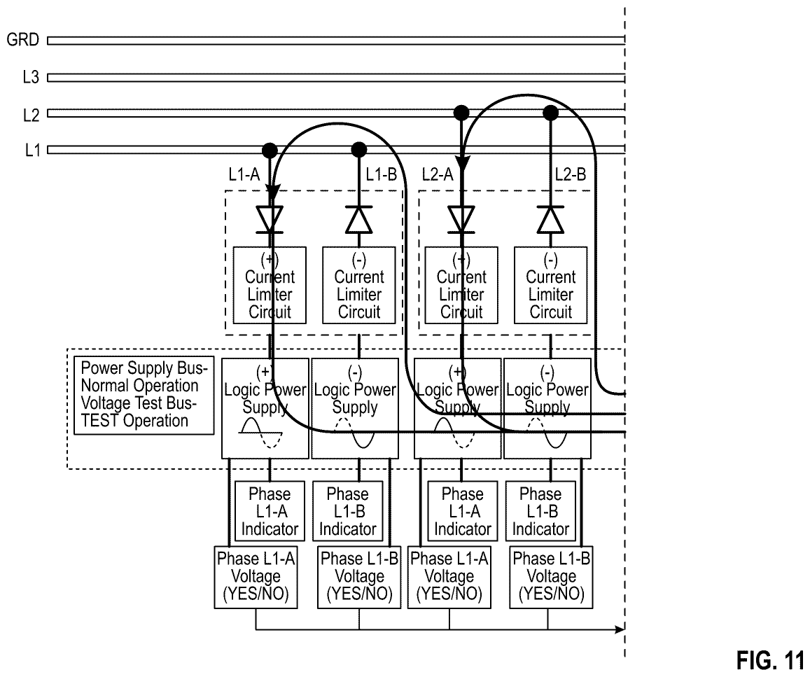

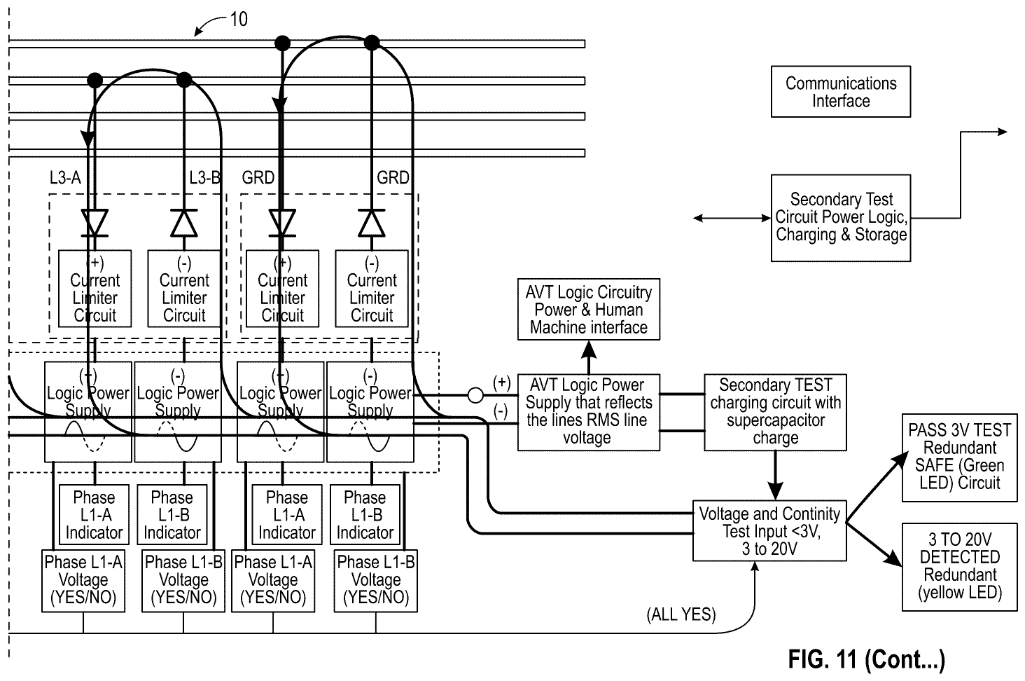

FIG. 11 is a block diagram illustrating test operation for a continuity test. During a test operation, a continuity test may be performed in a direction as shown where a signal is generated by the secondary test circuit. During a test operation, the power supply bus now functions as a voltage test bus.

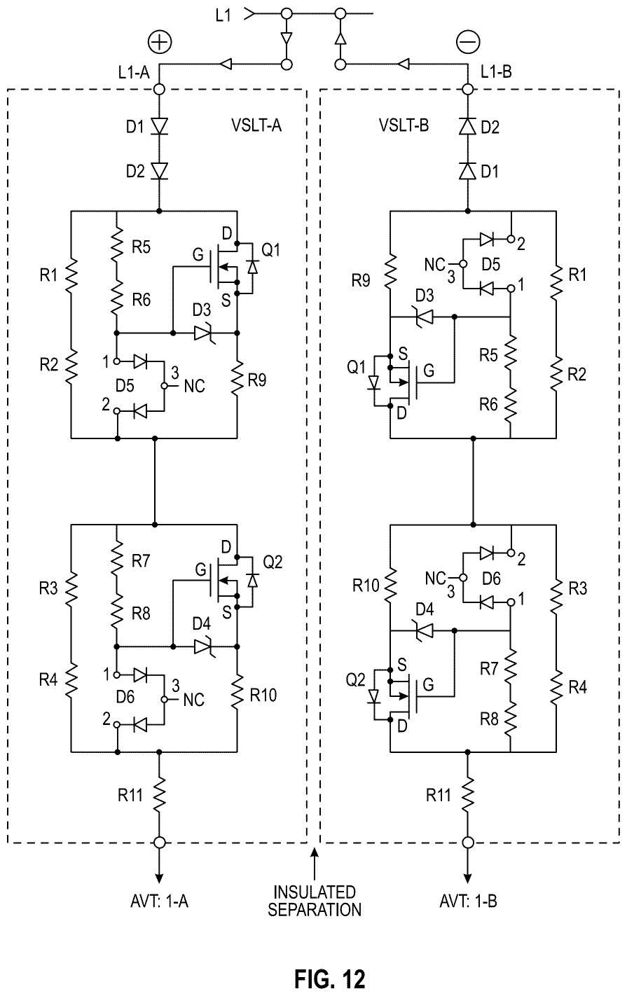

FIG. 12 illustrates one example of a VSLT module 50 in more detail. The VSLT module 50 shown is connected to a source conductor or line input L1 which may be the L1 phase conductor of a 3-phase power connection. Note there are two separate connections to L1. At each connection to L1 there is a first diode and a second diode, with the diode placed in opposite directions for L1-A and L1-B.

At L1-A there are rectifying diodes D1 and D2 in a forward direction. The presence of multiple diodes allows for additional redundancy in the circuit in case of component failure resulting in a short circuit. The circuit provides for active input current limiting with the MOSFET. Gate voltage protection diodes D3, D4 which are Zener diodes are shown between the gate the source terminals of the MOSFET to protect from overvoltage. Resistors R9 and R10 are current limiting resistors. Schottky diodes D5, D6 are also shown. The different VSLTs, within the VSLT module 50 have insulated separation between each other.

Thus, the physical design of the VSLT PCBs may reduce harmonics/noise at the connection. In addition, using twisted pair 20 A WG also mitigates harmonics into the AVT In addition, because all the phases end up on one logic power bus, some of the harmonics on each phase have a cancelation effect on each other. In addition, the VSLT may be temperature compensated so if they get too hot or cold they still current limit to a desired amount such as 0.5 mA.

Generally, the VSLT module outputs current and voltage limited outputs of L1 for both directions. This is advantageous because the voltage and current are limited such that high current and/or high voltages are not directly connected to the panel portion of the AVT. This increases the safety of the AVT. In addition, it allows for a smaller size of AVT with less heat needed to be dissipated at the panel. Thus, there are significant advantages to the active current limiting provided by the VSLT module 50. It should be understood that this active current limiting may be used in other applications beyond AVTs, and its application is not to be limited to the specific applications shown and described.

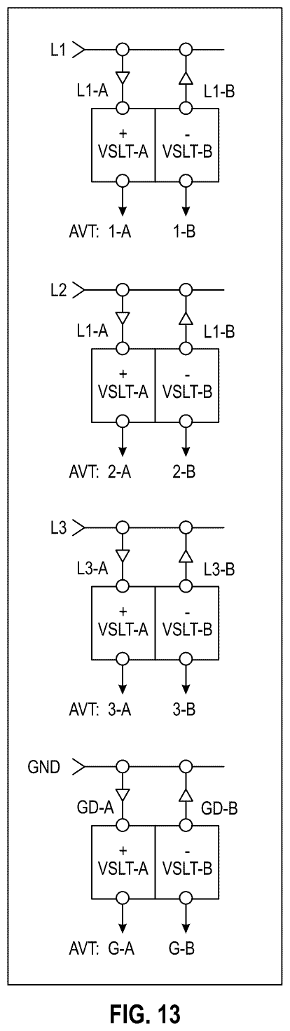

FIG. 13 illustrates multiple VSLT modules 50 where there is a VSLT module for each source conductor L1, L2, L3, GND for 3-phase power. The VSLT module 50 is advantageous in that it effectively reduces the magnitude of the output signal relative to the input signal. For example, a VSLT module 50 installed on one phase of a line voltage (typically 120-600 VAC) reduces the voltage on that phase to 7 VAC which is referenced to the high voltage side of the sine wave—as the line voltage goes up and down—the 7V remains steady. With 600 VAC on L1, L2, & L3 and zero VAC on GRD, the internal 3-phase power supply ground reference inside the VSLT would be 600 VAC (square root of 3)=346VRMS. As the line voltage gets to 7.8V (approx.), the voltage presence LEDs stop illuminating. As the line voltage approaches zero/GRD, the voltage on the power supply bus of the AVT approaches zero, the internal AVT ground reference also approaches zero. The internal power supply bus (3-phase bus) presents the highest voltage on L1 or L2 or L3 or GRD to be detected during the TEST function-so if L1=0V, L2=2.4V, L3=0.5V and GRD=0.1V, then the TEST circuit input will be 2.4V-PASS. The injected TEST voltage for the continuity TEST is 3.4V, so the voltage presence LEDs will not illuminate during the TEST.

Thus, the internal floating DC Common reference is not at GRD during normal operation, but because it is floating and goes to zero/GRD when there is no line voltage thereby allowing for the use of the same circuit and pathway for the 3V TEST and the Continuity TEST.

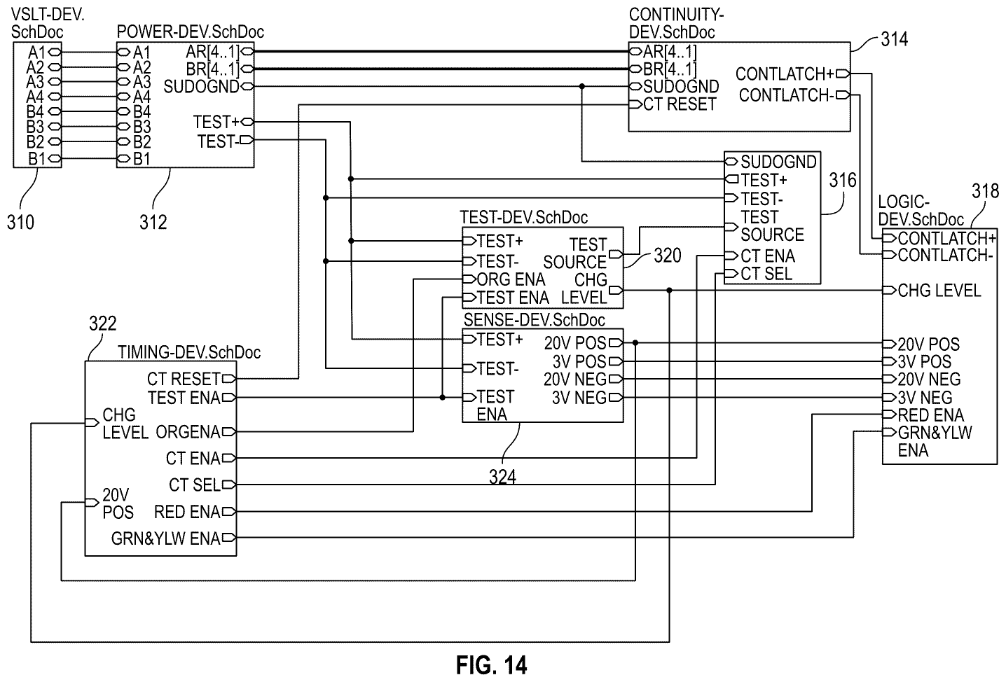

FIG. 14 illustrates a circuit diagram for one example of an analog circuitry for the AVT for three phase power. A VSLT device 310 is shown. Although a VSLT device is shown consolidated into a single block, it is to be understood that multiple VSLT devices may be used in the manner shown and/or described throughout including separate VSLT for each of the different line connections. The output from the VSLT device 310 is received at a power circuitry 312. One purpose of the power circuitry 312 is to receive inputs from the VSLT and to use indicators such as LEDs to show voltage presence on each of the input lines (either positive or negative).

The continuity circuitry 314 is used to administer a continuity test as a part of a test sequence. The continuity circuitry 314 may include latches for latching outputs of the continuity test. Switching circuitry 316 may be used to enable or disable the test function. The switching circuitry may receive as inputs from timing circuitry 322 to enable a continuity test as well as input from the test circuitry 320. Outputs may then be provided to the test circuitry 320. The timing circuitry may be used to enable a test phase once a user interactive button is pressed or other means is used to initiate a test. The timing circuitry may provide for setting a signal high for a time period and then to reset after the time period is over. The timing circuitry may also perform other timing functions including to create different waveforms including a waveform to produce a flashing signal to indicate low charge for the secondary power source which may, for example, be a supercapacitor.

Various circumstances will prevent operation of or otherwise disable the test function. For example, if any of the eight different VSLT source connections are not connected then the test function is disabled. If there is low voltage for the secondary power source, then the test circuit is disabled unless and until it is sufficiently charged to complete a test.

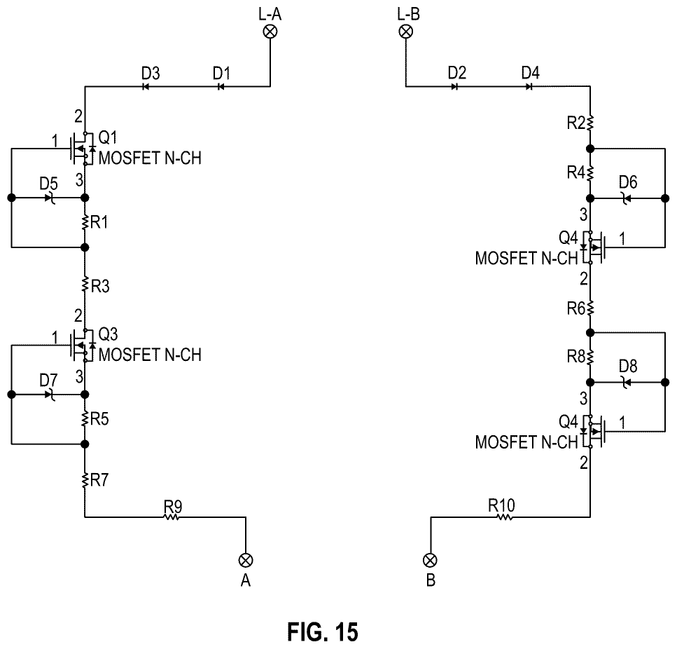

FIG. 15 further illustrates an example of the VSLT module.

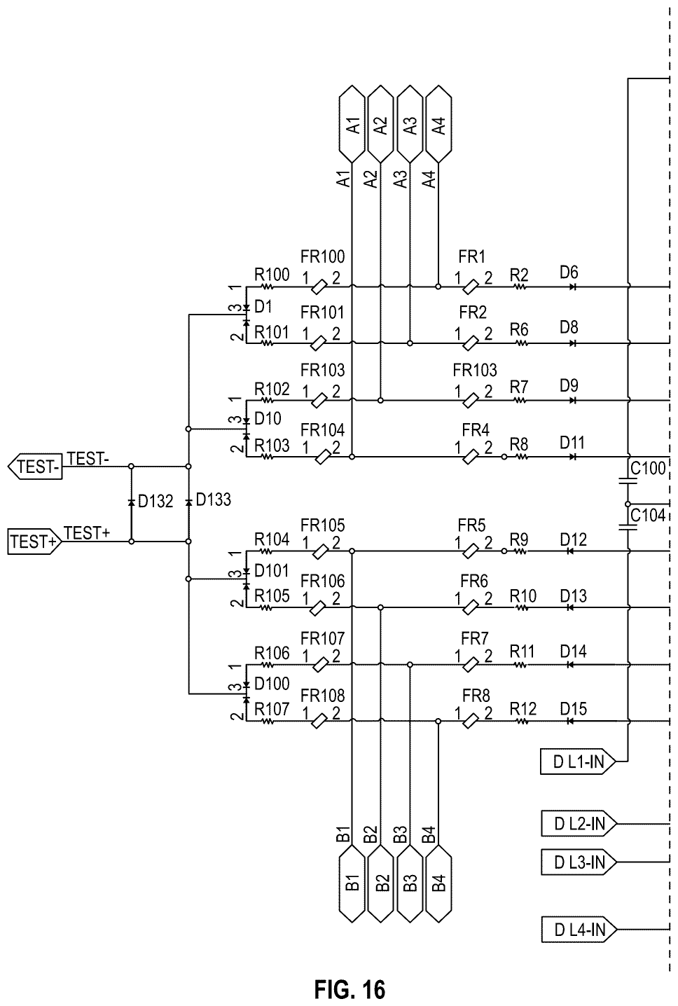

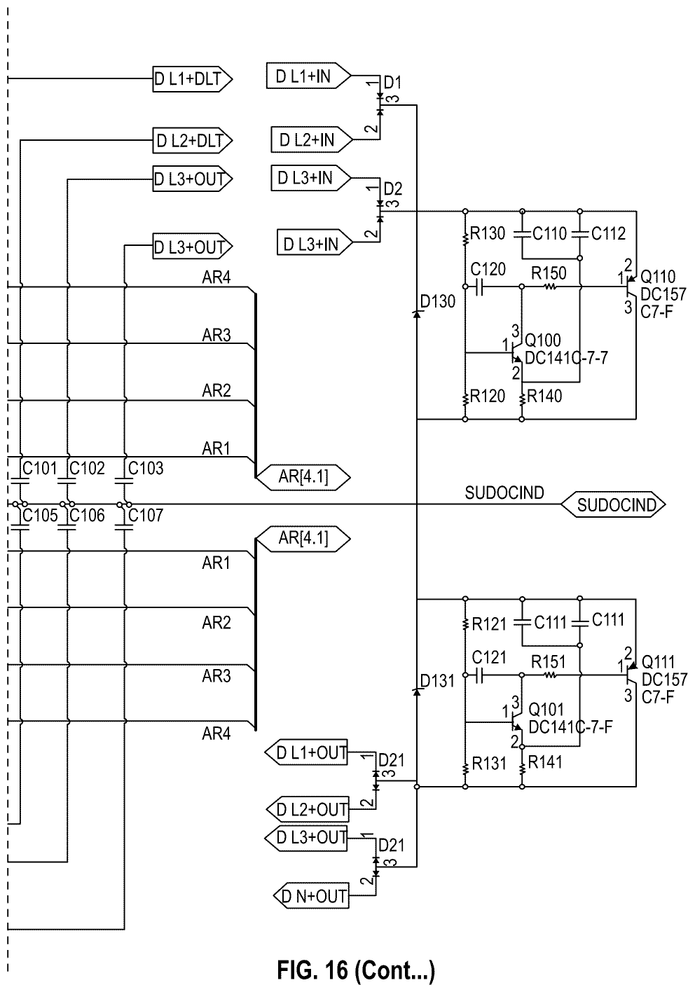

FIG. 16 illustrates the power circuitry in more detail. It should be understood that the circuitry shown is analog circuitry and implementing the functionality of the AVT using analog circuitry may be advantageous in various ways as previously explained. As shown in FIG. 16, there are two LEDs for each phase indicative of positive or negative voltage.

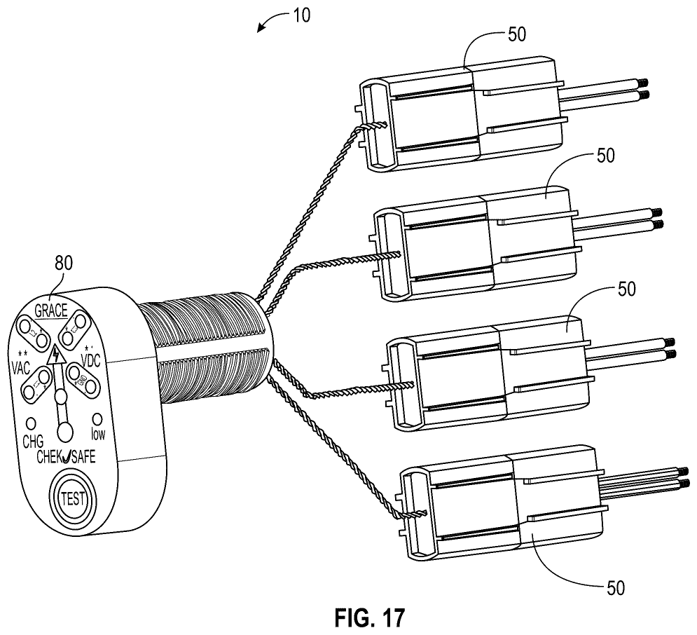

FIG. 17 illustrates the VSLT modules 50 with lead wire to source. As shown in FIG. 17 instead of connectors wires may be hardwired. For example, #14 AWG termination wires may be used. Each of the VSLT modules 50 may include voltage sensing and current limiting circuitry on a printed circuit board or otherwise. The AVT is shown with a face 80 which includes voltage presence LED pairs, a 3-20 volt LED, a “de-energized” status LED, a low charge LED, a charging LED, and a test initiate LED associated with a test button.

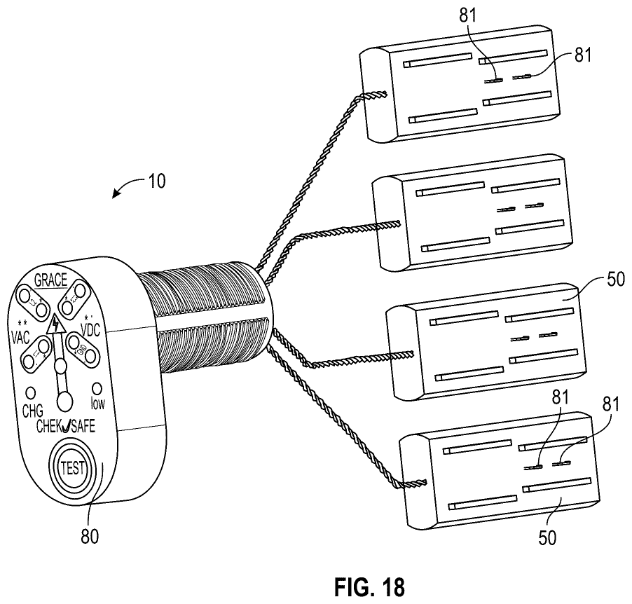

FIG. 18 illustrates the VSLT assembly modules with stabs for the source connection. There are two termination stabs 81 for each VSLT module 50. The terminations stabs 51 provide for a simple and convenient method and structure for connecting source conductors to the AVT. This is a significant benefit as it significantly reduces the amount of time required to install an AVT while also providing an error proof connection.

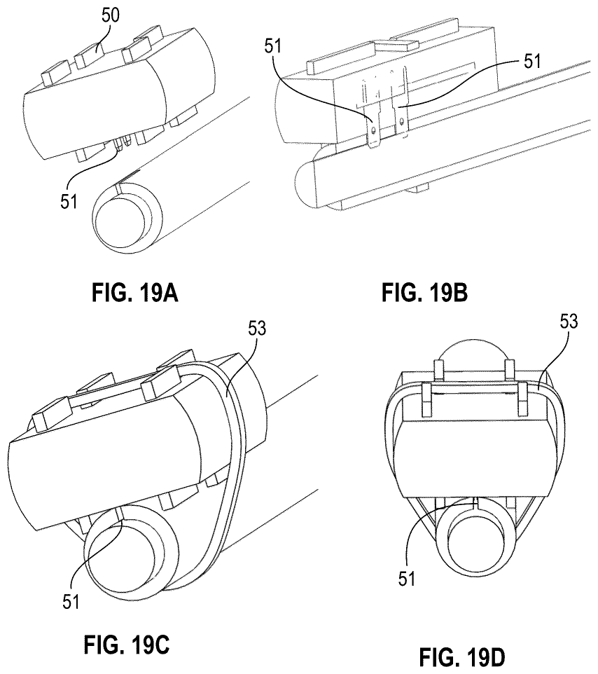

FIG. 19A, FIG. 19B, FIG. 19C, and FIG. 19D further illustrate a VSLT module with dual stabs to make error-proof connection to source. As shown in FIG. 19A there is a VSLT module 50 with two source connection stabs as well as a source conductor. As shown in FIG. 19B, the two source connection stabs connect to the source conductor. Then as shown in FIG. 19C, the VSLT module 50 may be secured to the source conductor such as with a tie or restraint 53. FIG. 19D shows this connection from a different view.

Each of the stabs 51 is spaced apart to make a connection at a different point on the source conductor. Such a design is integral to the functioning of the VSLT module and continuity testing. The stabs may be aligned along a longitudinal axis of the source conductor. The presence of the dual stabs further promotes a stable mechanical as well as electrical connection. The ability to the use the VLST directly connected to a source conductor is highly advantageous as it can decrease the size of the AVT needed on the face of a panel. Thus, the use of the dual stabs contributes to numerous advantages as have been shown and/or discussed.

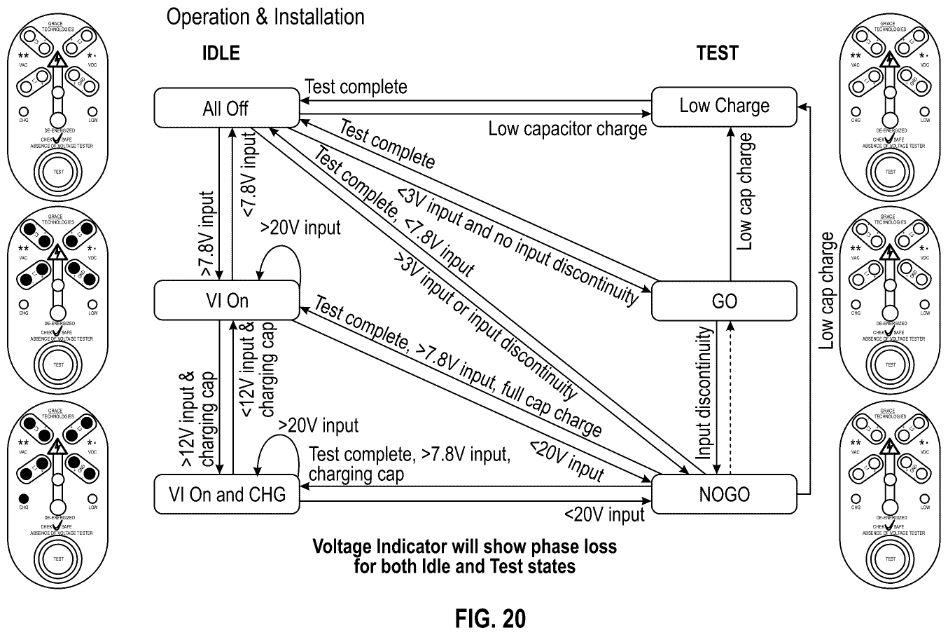

FIG. 20 further illustrates operation of the AVT in both an idle state and a test state. The design of the face panel allows significant amounts of information to be conveyed to a work in order to improve safety during absence of voltage testing. In particular, when a determination is made that there is no LED illumination in the idle state and less than about 3 volts present and no input discontinuity in the test state, then a user will receive a positive indicator (such as illumination of a green LED) that they can proceed. If that is not the case, then the user does not receive the positive indicator.

Although the embodiments shown emphasize AC voltages, such as those associated with three-phase power, it is to be understood that the AVT and various circuitry and methodology described may also be applied to DC voltages and monitoring DC voltages. Although three phase power is shown, it to be further understood that the AVT may function within or be configured to function within other environments with other types of source connectors. Moreover, in some embodiments, logic or functionality may be performed by digital circuitry instead of or in addition to analog circuitry. It is to be further understood that particular component selection and values of components may be dependent upon a specific implementation or operating environment. In addition, it is to be understood that various aspects may be implemented with any number of different types of components.

The term “absence of voltage” is used herein. It is to be understood that “absence of voltage” testing involves not only confirming that voltage presence indicators are off (which is indicative of absence of voltage but not conclusive) and then confirming that the circuit is functional such as through performing continuity test.

Although various examples have been shown and described, it is to be understood that there may be variations in the number and placement of various visual indicators. In addition, there may be variations with respect to the specific threshold used. In addition, it is contemplated that additional indicators may be used to provide additional thresholds. It is to be further understood that different features of different embodiments may be combined. It is also to be understood that although AVTs are shown and described, various novel components and systems may be used in other applications including in electrical safety devices, power supplies, or otherwise.

What is claimed is:

1. An absence of voltage tester (AVT) for detecting the absence of voltage associated with a power source, the AVT comprising:
a panel mount assembly;
circuitry at the panel mount assembly for detecting presence of voltage;
a supervisory test circuit within the circuitry for performing testing;
a power supply conversion circuit;
separate VSLT assembly modules for each phase of the power supply conversion circuit; and
wherein the power supply conversion circuit is physically distributed between the circuitry at the panel mount assembly and the separate VSLT assembly modules.

2. The AVT of claim 1 wherein each of the separate VSLT assembly modules comprises two voltage sense lead and continuity terminations.

3. The AVT of claim 2 wherein each of the separate VSLT assembly modules comprises two voltage sensing leads for physical connection with a load source conductor of the power source.

4. The AVT of claim 3 wherein each of the separate VSLT assembly modules comprises a first voltage sense lead and continuity termination printed circuit board and a second voltage sense lead and continuity termination (VSLT) printed circuit board.

5. The AVT of claim 4 wherein each VSLT is configured to rectify half of a sine wave signal on the load source conductor.

6. The AVT of claim 3 wherein the load source conductor comprises at least one of a wire, a lug, a fuse block, an isolator, a circuit breaker, and a busbar.

7. The AVT of claim 3 wherein the load source conductor comprises a heat sink.

8. The AVT of claim 1 wherein the separate VSLT assembly modules are integrated into a fused disconnect switch.

9. The AVT of claim 1 wherein the separate VSLT assembly modules are integrated into a circuit breaker.

10. The AVT of claim 1 wherein the separate VSLT assembly modules are integrated into an isolation switch.

11. The AVT of claim 1 wherein the separate VSLT assembly modules are integrated into a disconnect or knife switch without fuse.

12. The AVT of claim 1 wherein the separate VSLT assembly modules are integrated into a galvanically isolated air gap device.

13. The AVT of claim 1 wherein the separate VSLT assembly modules are remote from the panel mount assembly.

14. The AVT of claim 1 further comprising a protective wrap configured to protect the separate VSLT assembly modules.

15. The AVT of claim 14 wherein the AVT is configured for installation by inserting the protective wrap and the separate VSLT assembly modules disposed therein through a hole in a panel.

16. A power supply conversion circuit, the power supply conversion circuit comprising:
a plurality of separate VSLT assembly modules, one of the plurality of separate VSLT assembly modules for each phase of the power supply conversion circuit,
wherein each of the separate VSLT assembly modules comprises a first voltage sense lead and continuity termination (VSLT) printed circuit board and a second voltage sense lead and continuity termination (VSLT) printed circuit board and wherein the first VSLT PCB is electrically connected to a source conductor for the phase at a first VTL connection point and wherein the second VSLT PCB is electrically connected to the source conductor for the phase at a second VTL connection point and a conductive bridge of the source conductor extends between the first VTL connection point and the second VTL connection point; and
circuitry at a panel mount assembly electrically connected to each of the plurality of separate VSLT assembly modules.

17. The power supply conversion circuit of claim 16 wherein each VSLT is configured to rectify half of a sine wave signal on the source conductor.

18. The power supply conversion circuit of claim 16 wherein each of the plurality of separate VSLT assembly modules is integrated into an isolator.

19. The power supply conversion circuit of claim 18 wherein the source conductor is a heat sink.

20. The power supply conversion circuit of claim 16 wherein the circuitry at the panel mount assembly is electrically connected to each of the plurality of the separate VSLT assembly modules using wiring of a smaller gauge sufficient for current limited signals from each of the plurality of the separate VSLT assembly modules.

21. The power supply conversion circuit of claim 20 wherein the wiring comprises twisted pair wiring.

22. The power supply conversion circuit of claim 16 wherein each of the plurality of separate VSLT assembly modules are positioned within protective wrap.

23. The power supply conversion circuit of claim 16 wherein the plurality of separate VSLT assembly modules comprises four separate VSLT assembly modules, each of the four separate VSLT assembly modules comprising two VSLT circuits.

24. The power supple conversion circuit of claim 16 wherein each of the VLST assembly modules comprises dual stabs for connection with a corresponding source connector.

25. A voltage sense lead and continuity termination (VSLT) assembly module for use with a source conductor of a power source, the VSLT assembly module comprising:
a first voltage sense lead and continuity termination (VSLT) circuit;
a second voltage sense lead and continuity termination (VSLT) circuit;
wherein the first VSLT circuit is electrically connected to the source conductor for a phase of the power source at a first voltage termination lead (VTL) connection point;
wherein the second VSLT circuit is electrically connected to the source conductor for the phase of the power source at a second voltage termination lead (VTL) connection point; and
wherein the first VTL connection point and the second VTL connection point are positioned at the source conductor such that a conductive bridge of the source conductor extends between the first VTL connection point and the second VTL connection point.

26. The VSLT assembly module of claim 25 wherein the first VSLT circuit performs half wave rectification of a signal on the source conductor.

27. The VSLT assembly module of claim 26 wherein the second VSLT circuit performs half wave rectification of the signal on the source conductor.

28. The VSLT assembly module of claim 25 wherein the VSLT assembly module is configured to generate a signal which enables current flow for a voltage presence function of an absence of voltage tester (AVT).

29. The VSLT assembly module of claim 25 wherein a first connection between the first VSLT circuit and the source conductor is directly on the VSLT assembly module.

30. The VSLT assembly module of claim 29 wherein a second connection between the second VSLT circuit and the source conductor is directly on the VSLT assembly module.

31. A system comprising a plurality of the VSLT assembly modules of claim 25 enclosed within a protective wrap along with wiring between each of the VSLT assembly modules and a panel mount assembly.

32. A system comprising a plurality of the VSLT assembly modules of claim 25 mechanically connected together.

33. The system of claim 32 wherein the plurality of the VSLT assembly modules are mechanically connected together by snapping or ganging.

34. A system comprising a plurality of the VSLT assembly modules of claim 25, the plurality of the VSLT assembly modules comprising a L1 VSLT assembly module for use with an L1 source conductor, a L2 VSLT assembly module for use with an L2 source conductor, a L3 VSLT assembly module for use with an L3 source conductor, and a GND power conversion module for use with a GND source conductor.

35. The system of claim 34 wherein there is a separate mechanical termination for each of 8 leads.
